(19) United States
(12) Patent Application Publication
(10) Pub. No.: US 2014/0063725 A1
(43) Pub. Date: Mar. 6, 2014

(54) CASING OF SOLID STATE DISK AND SOLID STATE DISK HAVING THE SAME

(71) Applicants: Wei-Hau CHEN, New Taipei City (TW); Tien-Chen HUANG, New Taipei City (TW); Chen-Fong LIN, New Taipei City (TW)

(72) Inventors: Wei-Hau CHEN, New Taipei City (TW); Tien-Chen HUANG, New Taipei City (TW); Chen-Fong LIN, New Taipei City (TW)

(73) Assignee: CompTake Technology Inc.

(21) Appl. No.: 13/597,255

(22) Filed: Aug. 29, 2012

(51) Int. Cl. H05K 5/03; G06F 1/16

(52) U.S. Cl. 361/679.33; 312/223.2

(57) ABSTRACT

A solid state disk includes a circuit board and a casing. The casing comprises a first cover and a second cover. The circuit board is provided in the first cover. Each side of the first cover is provided with a plurality of first combining portions. Each side of the second cover is provided with a plurality of second combining portions at positions corresponding to those of the first combining portions respectively. The second combining portions are buckled to the first combining portions respectively. Each first combining portion has an extension section extending from the first cover. The extension section of the first combining portion extends to be buckled to the second combining portion. Thus, the first cover and the second cover cannot be detached easily. When the casing is detached, the extension section will get broken, thereby preventing undesired detachment.

### BACKGROUND OF THE INVENTION

1. Field of the Invention

The present invention relates to a solid state disk, and in particular to a solid state disk having a casing provided with a buckling means for preventing undesired detachment.

2. Description of Prior Art

Solid state disk is a high speed storage medium in a form of memory. In comparison with the traditional hard disk, the solid state disk is not provided with mechanical parts, so that the solid state disk has a simple structure, a fast reading/writing speed, and a long lifetime. Thus, with the advancement of the manufacturing procedure of the memories, the solid state disks are gradually used more and more widely.

The existing solid state disk comprises a memory circuit board and a casing. The memory circuit board is received in the casing. The casing comprises an upper cover and a lower cover both connected together by screw elements or other fixing means. Thus, after being manufactured from the factory and before being delivered to the customs, the memory circuit board of the conventional solid state disks may be removed and replaced by an inferior memory circuit board. As a result, the customers may not be aware of this, so that the rights and interests of the customers are affected.

### SUMMARY OF THE INVENTION

The present invention relates to a casing of a solid state disk capable of preventing detachment and a solid state disk having such a casing.

The present invention provides a solid state disk comprising a circuit board and a casing. The casing comprises a first cover and a second cover. The inside of the first cover is provided with a plurality of positioning pieces buckled to the edges of the circuit board to thereby fix the circuit board into the first cover. Each side of the first cover is provided with a plurality of first combining portions. Each side of the second cover is provided with a plurality of second combining portions at positions corresponding to those of the first combining portions respectively. The second combining portions are buckled to the first combining portions respectively. Each first combining portion has an extension section extending from the first cover. The extension section of the first combining portion extends to be buckled to the second combining portion.

Preferably, in the solid state disk, the circuit board is provided with an electrical connector. The first cover is provided with an insertion port corresponding to the electrical connector. The electrical connector is exposed to the first cover via the insertion port.

Preferably, in the solid state disk, two first combining portions are provided on two opposite sides of the insertion port respectively.

Preferably, in the solid state disk, the second combining portions are integrally formed inside of the second cover.

Preferably, in the solid state disk, the first combining portion is an engaging frame, and the second combining portion is a hook corresponding to the engaging frame.

In the present invention, all sides of the first cover are fastened to all sides of the second cover respectively without being detached easily. Thus, when the casing is detached, the extension section will get broken, thereby preventing undesired detachment. In this way, the problem in prior art that the memory circuit board is replaced easily can be solved.

### BRIEF DESCRIPTION OF DRAWING

FIG. 1 is an exploded perspective view showing the solid state disk in accordance with a second embodiment of the present invention;

FIG. 2 is a cross-sectional view (I) showing the solid state disk in accordance with the second embodiment of the present invention; and

FIG. 3 is a cross-sectional view (II) showing the solid state disk in accordance with the second embodiment of the present invention.

### DETAILED DESCRIPTION OF THE INVENTION

The detailed description and technical contents of the present invention will become apparent with the following detailed description accompanied with related drawings. It is noteworthy to point out that the drawings is provided for the illustration purpose only, but not intended for limiting the scope of the present invention.

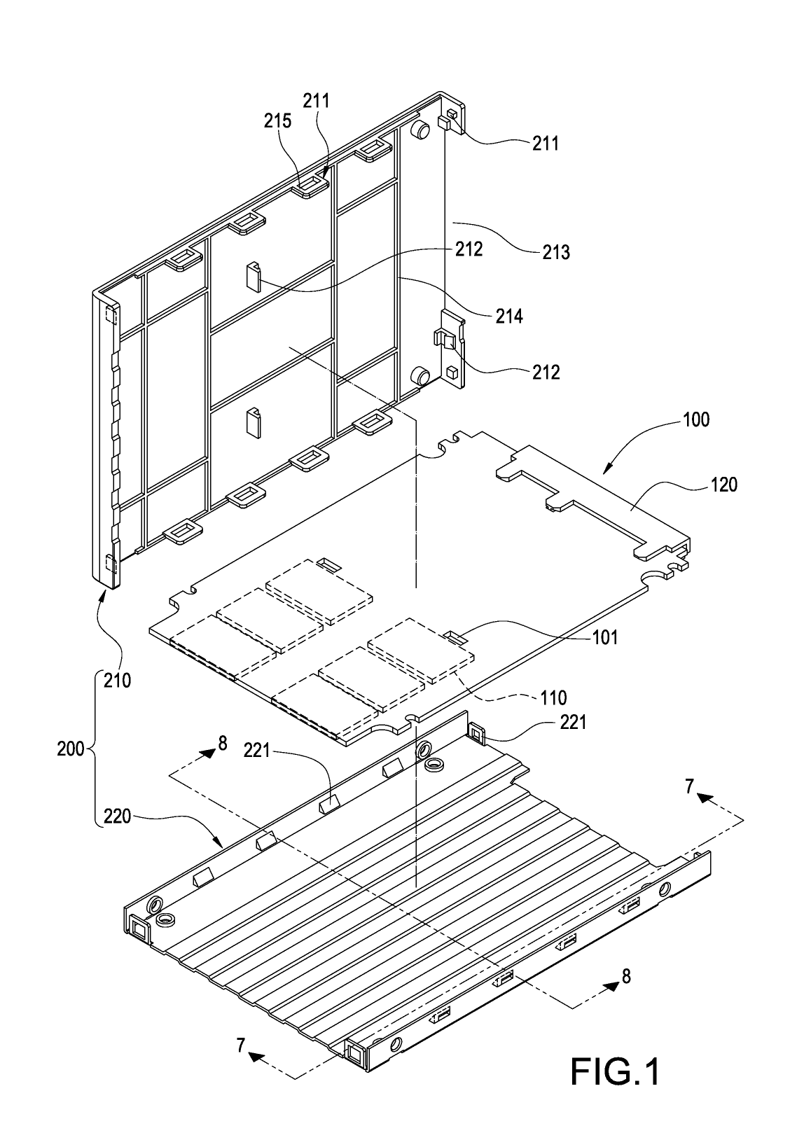

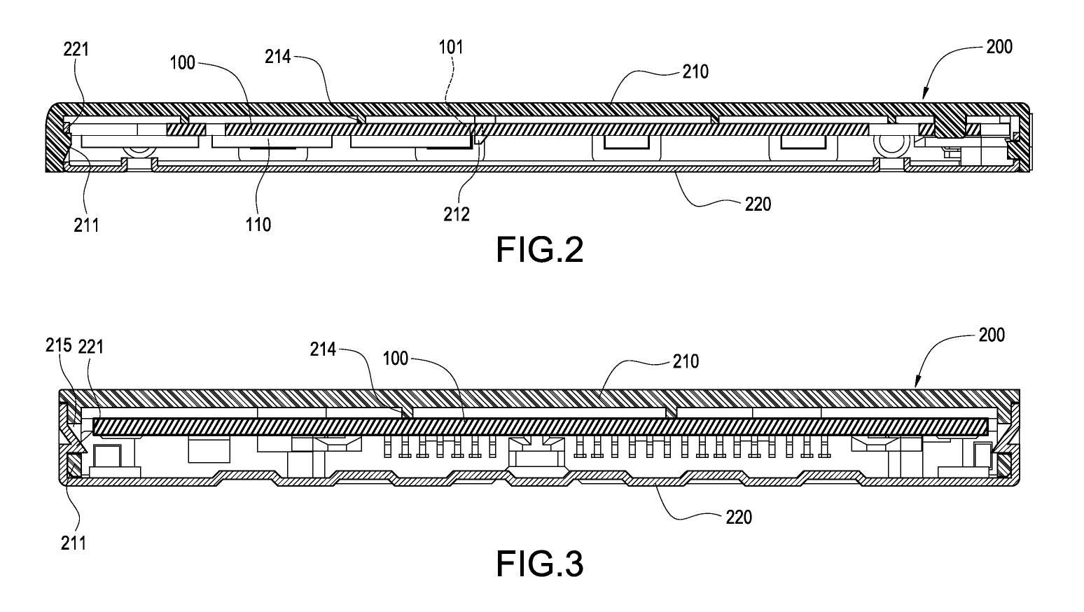

Please refer to FIGS. 1 and 2, which show the solid state disk of the second embodiment of the present invention. The solid state disk comprises a circuit board 100 and a casing 200. The casing 200 comprises a first cover 210 and a second cover 220. The interior of the casing 200 is used to accommodate the circuit board 100. The circuit board 100 is preferably provided with a plurality of memory chips and at least one electrical connector 120. In the present embodiment, the solid state disk preferably comprises one electrical connector 120. The electrical connector 120 has the standard of IDE, UATA, SATA or the like, but it is not limited thereto. The first cover 210 and the second cover 220 are made of elements of different hardness. In the present embodiment, preferably, the first cover 210 and the second cover 220 are made of plastic materials and metallic materials respectively.

The first cover 210 is formed into a rectangular shape and preferably made of plastic materials. The circuit board 100 is provided in the first cover 210. The first cover 210 is provided with an insertion port 213 at a position corresponding to that of the electrical connector 120 on the circuit board 100. The electrical connector 120 is exposed to the first cover 210 via the insertion port 213. Four sides of the first cover 210 are provided with a plurality of first combining portions 211 respectively. Two of the first combining portions 211 are provided on two opposite sides of the insertion port 213, thereby avoiding the position of the electrical connector 120. The inside of the first cover 210 is provided with a plurality of positioning pieces 212. In the present embodiment, the inside of the first cover 210 is preferably provided with four positioning pieces 212. Each of the positioning pieces 212 integrally protrudes from the inside of the first cover 210 to be bucked to the circuit board 100, thereby fixing the circuit board 100 into the first cover 210. The circuit board 100 is provided with a plurality of positioning holes 101 at positions corresponding to two of the positioning pieces 212. The positioning pieces 212 are buckled into the positioning holes 101, and the remaining two positioning pieces 212 are buckled to the edge of the circuit board 100. The inside of the first cover 210 is preferably formed with a plurality of reinforcing ribs 214 for reinforcing the structural strength of the first cover 210.

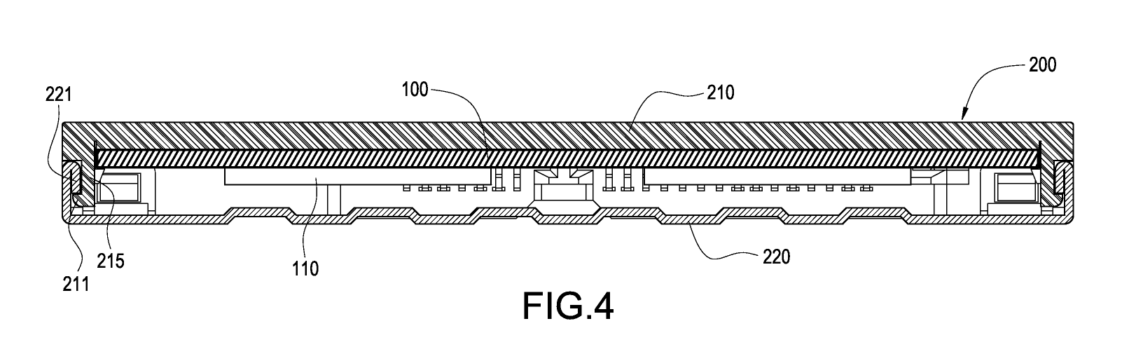

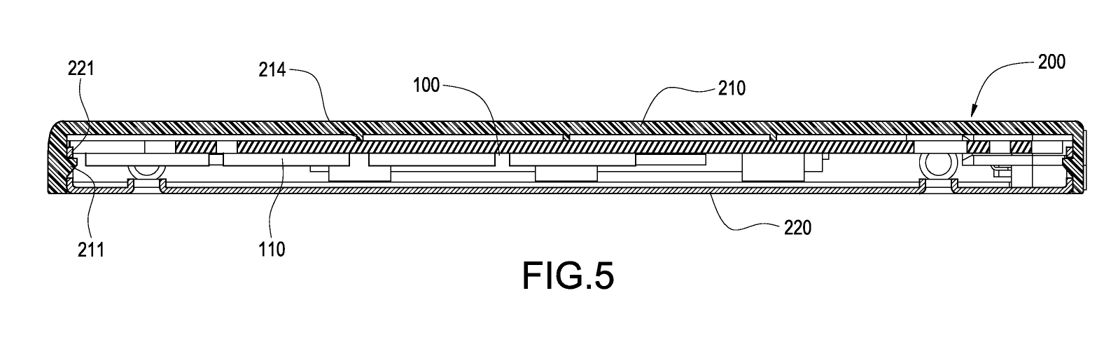

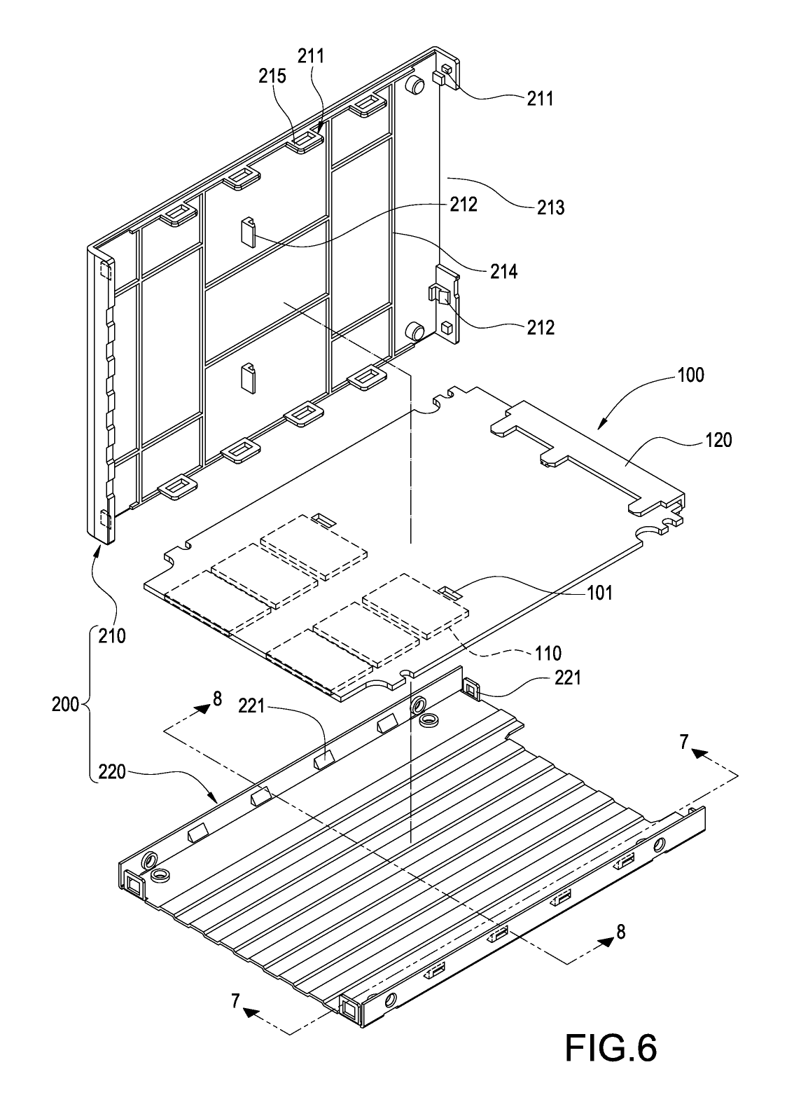

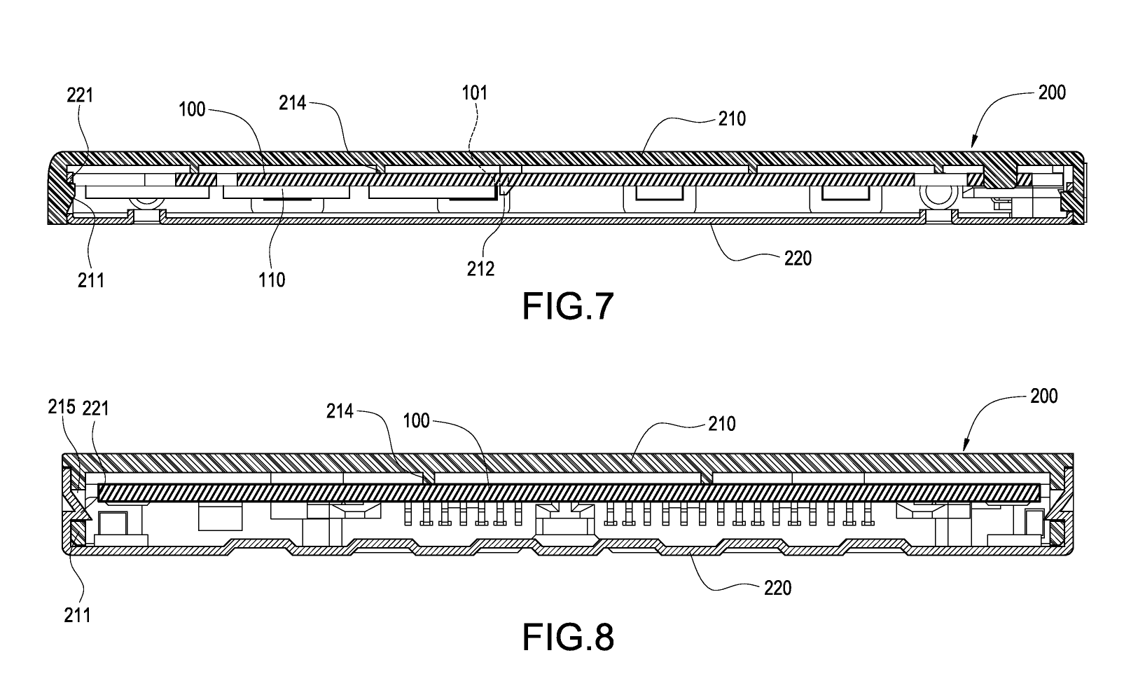

Please refer to FIGS. 1 and 3. The second cover 220 is formed into a rectangular shape and preferably made of metallic materials. Four sides of the second cover 220 are provided with a plurality of second combining portions 221 at positions corresponding to those of the first combining portions 211 respectively. In the present embodiment, the first combining portion 211 may be configured as a protrusion or engaging frame. The second combining portion 221 is integrally formed inside the second cover 220. In the present embodiment, each of the second combining portion may be configured as an engaging frame or protrusion complementary to the first combining portion 211. The engaging frame is a frame extending from the edge of the second cover 220. In the present embodiment, the frame is formed into a rectangular shape, but it is not limited thereto. For example, the first combining portion 211 is a protrusion formed inside the first cover 210, and the second combining portion 221 is an engaging frame provided on the second cover 220. If the first combining portion 211 is an engaging frame formed on the first cover 210, the second combining portion 221 is a hook formed inside the second cover 220.

The first combining portion 211 has an extension section 215 extending from the first cover 210. The extension section 215 of the first combining portion 211 extends to the second combining portion 221 to be buckled to the second combining portion 221. When the buckled first combining portion 211 and the second combining portion 221 are detached with each other, the extension section 215 will get broken due to the force exerted by the second combining portion 221.

In the solid state disk of the present invention, four sides of the first cover 210 and the second cover 220 are provided with the first combining portions 211 and the second combining portions 221 corresponding to each other respectively. By this arrangement, the first cover 210 can be firmly buckled to the second cover 220 without being detached from each other easily. Further, the first cover 210 and the second cover 220 are made of materials of different hardness. When the buckled first cover 210 and the second cover 220 are detached from each other, a part of the plastic first combining portion 211 will be pulled by the metallic second combining portion 221, thereby breaking the extension section 215 which is weak in structure. Therefore, by judging whether the first combining portion 211 of the solid state disk of the present invention is broken or not, the user can recognize whether the first cover 210 and the second cover 220 already have been detached from each other or not.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

1-8. (canceled)

9. A solid state disk, including:
a circuit board; and
a casing comprising a first cover and a second cover, the inside of the first cover being provided with a plurality of positioning pieces buckled to the edge of the circuit board to thereby fix the circuit board into the first cover, each side of the first cover being provided with a plurality of first combining portions, each side of the second cover being provided with a plurality of second combining portions at positions corresponding to those of the first combining portions respectively, the second combining portions being buckled to the first combining portions respectively, each first combining portions having an extension section extending from the first cover, the extension section of the first combining portion extending to be buckled to the second combining portion.

10. The solid state disk according to claim 9, wherein the circuit board is provided with an electrical connector, the first cover is provided with an insertion port at a position corresponding to the electrical connector, the electrical connector is exposed to the first cover via the insertion port.

11. The solid state disk according to claim 10, wherein two of the first combining portions are provided on two opposite sides of the insertion port.

12. The solid state disk according to claim 9, wherein the second combining portions are integrally formed inside the second cover.

13. The solid state disk according to claim 9, wherein the first combining portion is an engaging frame, and the second combining portion is a hook corresponding to the engaging frame.
